(19) United States
(12) Patent Application Publication
(10) Pub. No.: US 2009/0267617 A1
(43) Pub. Date: Oct. 29, 2009

(54) APPARATUS AND METHOD FOR MEASURING SALINITY OF A FLUID BY INDUCTANCE

(76) Inventors: Samad Seyfi, Longmont, CO (US); Christopher Scott Brown, Longmont, CO (US)

Correspondence Address: COCHRAN FREUND & YOUNG LLC, 2026 CARIBOU DR, SUITE 201, FORT COLLINS, CO, 80525, US

(21) Appl. No.: 12/410,443

(22) Filed: Mar. 24, 2009

Related U.S. Application Data
(60) Provisional application No. 61/039,037, filed on Mar. 24, 2008.

(51) Int. Cl. G01R 27/26

(52) U.S. Cl. 324/655

(57) ABSTRACT

A salinity sensor for sensing or measuring salinity of a static or flowing fluid without contacting the fluid includes magnetic coil with a gapped core and a conduit for the fluid positioned in the gap in the core. The magnetic coil and the portion of the magnetic field produced by the coil that extends through the fluid in the gap are part of an LC or LCR circuit that can be driven to resonant frequency for a fluid of known salinity, which may include, but is not limited to, a fluid having zero salinity, as indicated by a peak output voltage on the circuit. Then, when the salinity of the fluid in the gap changes or a fluid with a different salinity is placed in the gap, the characteristics of the LC or LCR circuit, including inductance L and resonant frequency, change, and such changes can be detected and measured as an indication of the salinity of the fluid in the gap.

### CROSS-REFERENCE TO RELATED APPLICATION

This application is a nonprovisional application of provisional application No. 61/039,037 filed Mar. 24, 2008, which is incorporated herein by reference.

### BACKGROUND OF THE INVENTION

1. Field of the Invention

This invention is related to apparatus and methods for measuring salinity of a fluid, and, more specifically, to apparatus and methods for measuring salinity by inductance.

2. State of the Prior Art

Measurements of salinity of electrolytic solutions, including salinity of flowing fluids, are needed in many applications and processes and can be done in a variety of ways. One common method is to measure the electrical conductivity of a saline fluid as an indication of salinity. Saline solutions generally comprise salts of the alkali or alkaline earth metals dissolved in water or another solvent. The most common example of a saline solution is sodium chloride (NaCl) dissolved in water. The salt molecules, upon dissolution, dissociate into ions, i.e., cations (positively charged ions) and anions (negatively charged ions), which can move about in the solution and can conduct electric current. For the sodium chloride example, the NaCl dissociates into Na⁺ cations and Cl⁻ anions. Such solutions that contain free ions that can conduct electric current are known as electrolytic solutions or simply as electrolytes.

The correlation between salinity and the conductivity of electrolytic solutions is a well-established phenomenon. However, the movement of ions in the solution are constrained or inhibited to some extent by collisions with other particles that make up the solution, such as water molecules, other ions, contaminants, and the like. Therefore, while saline solutions are electrically conductive, the conductivity depends to a large extent on the amount of charge carrying ions in the solution and how quickly the energy of these ions may be dissipated as heat. In general, however, higher concentrations of ions in the solution result in higher electrical conductivity.

Since salinity, i.e., concentration of the salt ions, of an electrolytic solution is related to its electrical conductivity, measuring the electrical conductivity of the electrolytic solution and relating such measured electrical conductivity to salinity is a common method of determining the salinity of a fluid. The simplest of such methods is to place two electrodes a distance apart from each other in a sample of the fluid, and apply a voltage to the electrodes to place them at differential electrical potential so that an electric current flows through the fluid. The basic principle is that electric current will flow through the electrolytic fluid sample between the two electrodes, as explained above, and the conductivity can be determined by Ohm's Law, V=IR, where V is voltage, I is current, and R is resistance. The U.S. Pat. No. 3,283,240 is an example of an apparatus and method for determining conductivity of electrolytic solutions in this manner, although there are other variations.

While such direct conductivity measurements between two electrodes in an electrolytic solution, as described above, are reasonable for non-sterile solutions, non-contact methods are preferred in medical and other applications that require no contamination of the sample being measured. U.S. Pat. No. 4,740,755 is an example apparatus and method for non-contact measurement of the conductivity of an electrolytic fluid, such as dialysate, in which a primary wound toroid is used to set up a current in the sample and a secondary wound toroid detects the current. In this and similar conductivity measuring apparatus, the primary toroid or coil sets up an electromotive force (EMF) using the principle of Lenz's Law, which describes how freely moving charge carriers will set up a current to produce a magnetic field in opposition to changes in an external magnetic field.

The foregoing examples of the related art and limitations related therewith are intended to be illustrative and not exclusive. Other limitations of the related art will become apparent to those of skill in the art upon a reading of the specification and a study of the drawings.

### SUMMARY

The following summary, embodiments, and aspects thereof are described and illustrated in conjunction with systems, tools, and methods which are meant to be examples and illustrative, not limiting or exclusive in scope. In various embodiments, one or more of the above-described problems have been reduced or eliminated, while other embodiments are directed to other improvements.

The example embodiments are directed to measuring salinity of an electrolytic solution that can be static or flowing without using electrodes placed in the fluid, i.e., non-contact of the sensor components with the fluid. The electrolytic solution is positioned in or flowed through a gap in a core inductor that is driven at or near resonance in a tuned inductive-capacitive (LC) or inductive-capacitive-resistive (LRC) circuit to maintain a strong alternating magnetic field in the gap. Small changes in the inductance of the gapped inductor from changes in salinity of the solution in or passing through the gap can cause large changes in the overall behavior of the circuit, including, but not limited to, resonant frequency changes and voltage changes at a given frequency. Such changes can be detected and can provide a highly sensitive circuit for detecting or measuring salinity or changes in salinity that can be beneficial for sensing and/or measurements of salinity in a static fluid as well as real time measurements of salinity of a flowing fluid.

In addition to these example aspects and embodiments described above and hereafter, further aspects, embodiments and implementations will become apparent by reference to the drawings and by study and understanding of the following descriptions and explanations.

### BRIEF DESCRIPTION OF THE DRAWINGS

The accompanying drawings, which are incorporated herein and form a part of the specification, illustrate some, but not the only or exclusive, example embodiments and/or features. It is intended that the embodiments and figures disclosed herein are to be considered illustrative rather than limiting.

In the drawings:

FIG. 1 is a schematic, function block diagram of an example apparatus for measuring salinity of a fluid;

FIG. 2 is an enlarged cross-sectional view of the fluid tube illustrating an eddy current diagrammatically;

FIG. 3 is a calculated power response curve in relation to frequency of the input signal to the magnetic coil;

FIG. 4 is curve showing change in response voltage when distilled water sample fluid is replaced by a sample of 0.9% saline solution along with a calculated curve for a 6 micro-Henry change in the inductance of an ideal LCR circuit with similar starting values as the sensor head;

FIG. 5 is an isometric view of an example sensor head;

FIG. 6 is a cross-sectional view of the example apparatus for measuring salinity of a fluid with a gapped toroidal AC magnet device taken along the section plane 6-6 of FIG. 5;

FIG. 7 is a plan view of another example magnetic coil configuration; and

FIG. 8 is a perspective view of another example conduit configuration.

### DETAILED DESCRIPTION OF EXAMPLE EMBODIMENTS

For an overview of several example features, process stages, and principles of the invention, an example gapped toroidal core salinity sensor apparatus 10 is illustrated schematically and diagrammatically in FIG. 1. This gapped toroidal salinity sensor apparatus 10 is shown as one example implementation that demonstrates a number of features, processes, and principles used to achieve a highly sensitive salinity measurement of a stationary or flowing fluid, but it also is useful for other applications and can be made in different variations. Therefore, this description will proceed with reference initially to the example shown in FIG. 1 and then to other examples and variations, but with the understanding that the invention recited in the claims below can also be implemented in myriad other ways, once the principles are understood from the descriptions, explanations, and drawings herein, and that some, but not all, of such other embodiments, implementations, and enhancements are also described or mentioned below.

In this description, terms such as top, bottom, front, back, right, and left and similar adjectives in relation to orientation of the converter device and components of it refer to the manner in which the illustrations are positioned on the paper, not as any limitation to the orientations in which the apparatus can be used in actual applications. Also, the diagrams, views, and figures used or shown in the drawings are not drawn true to scale or in correct proportional relationships, which are not critical, but persons skilled in the art will be able to make and use the apparatus, once they understand the principles of the invention.

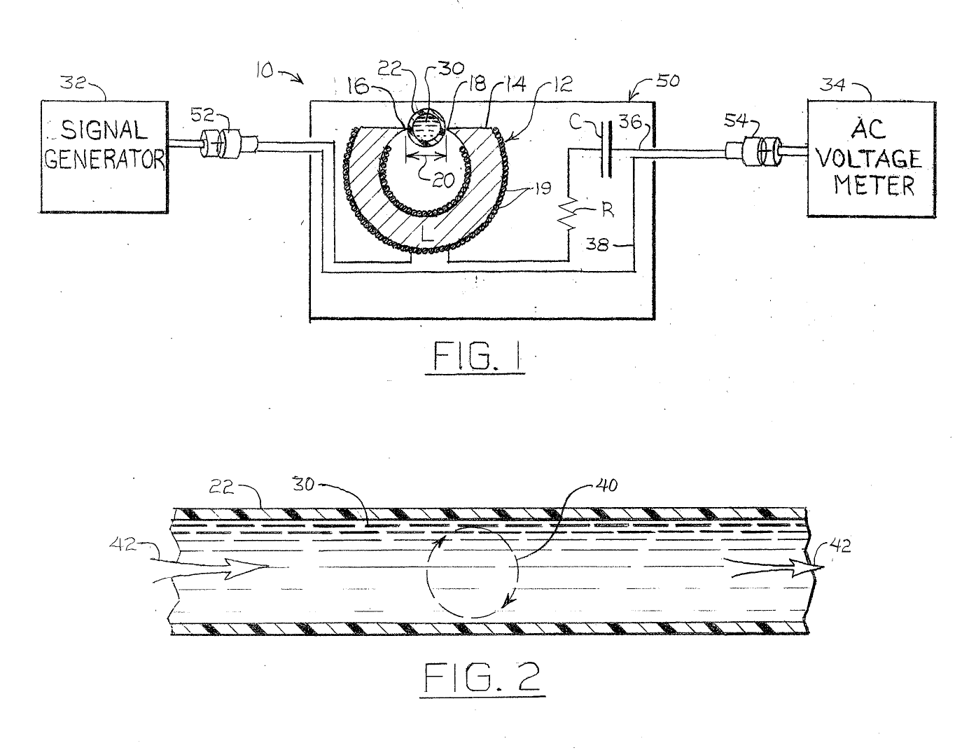

The example salinity sensor 10 shown in FIG. 1 includes a gapped toroidal magnetic coil 12 comprising a magnetic core 14 in the general shape of a toroid that is cut or shaped to have a gap 20 between opposing ends 16, 18 of the core 14 and a magnet wire (fine, insulated, electrically conductive wire) 19 wound around the core 14. A non-magnetic, electrically non-conductive, tube or conduit 22 is positioned in the gap 20 of the toroidal magnetic coil 12 for placing or flowing a fluid 30 to be tested or measured for salinity in or through the gap 20. A signal generator 32 is connected electrically to the magnetic wire winding 19 to drive the magnetic coil 12 with alternating current to produce a magnetic field with inductance L, and the electric current flows through a resistance R and capacitor C to an alternating current (AC) voltage meter 34, which detects the AC voltage between the two sides 36, 38 of the LRC circuit. The magnetic field produced by the magnetic coil 12 is focused at the gap 20, where a stray magnetic field is formed, and the fluid 30 in the conduit 22 positioned in the stray magnetic field in the gap 20 has an effect on the overall inductance L of the magnetic coil 12, thus affects the characteristics of the LRC circuit. If the fluid 30 is saline, i.e., an electrolyte, as explained above, the charge carriers (ions) in the fluid 30 will form eddy currents 40, as illustrated diagrammatically in FIG. 2, when they are exposed to a magnetic field that changes over time, as in the alternating magnetic field produced by the alternating current flowing in the coil 12. These eddy currents form in such a way as to oppose the changes in the magnetic field in accordance with Lenz's Law, and the strength of the eddy currents can be measured as a loss of power by dampening the alternating magnetic field, because some of the power used to generate the alternating field ends up as heat due to collisions of the charge carrying ions with other molecules in the solution. The power loss in the LRC circuit is manifested in a voltage drop, and the voltage in the LRC circuit can be measured by the AC voltage meter 34. Therefore, when calibrated, the voltage measured by AC voltage meter 34 is indicative of the salinity of the fluid 30 in the conduit 22. Generally, higher concentrations of ions in the solution, i.e., higher salinity, result in stronger eddy currents 40 produced by the alternating magnetic field, thus more power loss, and the power loss from such higher concentration of ions has a greater affect on the LRC circuit, which is manifested in a greater drop in voltage measured by the AC voltage meter 34.

Effectively, the salinity sensor apparatus 10 measures the salinity of the electrolyte solution 30 in the conduit 22, as explained above, by measuring how easily the solution conducts eddy currents in response to an alternating magnetic field, which is a function of the conductivity of the solution. The higher the salinity of the solution, the more easily the solution conducts eddy currents, and the more easily the solution conducts eddy currents, the more power is lost.

The power response curve of an LRC circuit, such as the LRC circuit shown in FIG. 1 and discussed above, has a lorentzian shape. An LRC circuit is most commonly a simple circuit comprising an inductor, a capacitor, and a resistor in series, such as the inductor comprising the magnetic coil and fluid 30 in the circuit of FIG. 1 along with the resistance R and capacitor C in FIG. 1. As mentioned above, the resistance R includes the resistance of the magnetic wire comprising the winding 19 and other resistance losses in the circuit, and it can, but does not have to, include one or more discrete resistors. Therefore, the resistor R in FIG. 1 is symbolic of the resistance of the circuit, not necessarily of a discrete resistor. The power response curve of the LRC circuit can be described by

$$P ( ω ) = \frac{A}{π} [ \frac{γ}{{( ω - {ω}_{0} )}^{2} + {γ}^{2}} ] \qquad ( Equation 1 )$$

where ω is angular frequency of the input signal from the signal generator 32 and related to the measured frequency f by ω=2πf, ω₀ is the resonant angular frequency, γ is the half-width of the power response curve at its half-maximum value (HWHM), and A is a normalization factor. For a series LCR circuit, such as that shown in FIG. 1, the resonant angular frequency is given by

$${ω}_{0} = \frac{1}{\sqrt{LC}} \qquad ( Equation 2 )$$

where L is the inductance value of the inductor and C is the capacitance value of the capacitor. The width of the power response in terms of the component values goes as

$$Δ ω = 2 γ = \frac{R}{L} \qquad ( Equation 3 )$$

where ideally R is the resistance in series with the circuit but, as explained above, can also include resistance from the inductor windings 19 and other resistances in the circuit.

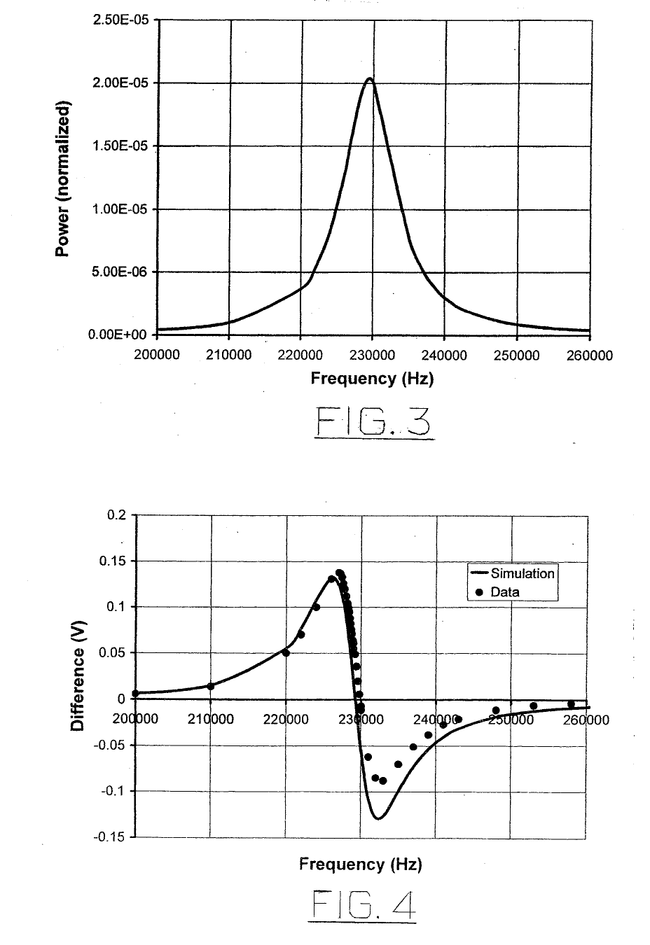

To operate the salinity sensor 10, the conduit 22 in the gap 20 can be filled first with distilled water, and the signal generator 32 is set at the resonant frequency f₀ of the LRC circuit with distilled water in the conduit 22. The resonant frequency f₀ is the frequency that produces the highest output voltage at the AC voltage meter 34. Then, the fluid 30 to be tested or measured for salinity is placed in the conduit 22 in the gap 20 instead of the distilled water, and, without changing the input voltage or the frequency f₀ of the signal produced by the signal generator 32, the output voltage of the circuit is measured at the AC voltage meter 34. If the fluid 30 is more saline than the distilled water, then the output voltage at the AC voltage meter 34 will be lower than it was for the distilled water, because the frequency f₀ that was resonant for the sensor 10 with distilled water in the conduit 22 and gap 20 will not be the resonant frequency for the sensor 10 with saline fluid 30 in the conduit 22 and gap 20. The salinity of the solution in the gap 20 of the inductor affects the overall inductance value L of the inductor, and therefore affects the frequency of the total LCR circuit. It is believed that the change in the circuit output is based on the change in the inductance L of the circuit caused by the change in salinity of the solution 30 as compared to the distilled water. Since the circuit is tuned to a particular resonant frequency f₀, e.g., at the peak of the curve in FIG. 3, a shift in the curve to the right or left without changing the height will result in a lower output voltage and lower power.

As an alternative, one could readjust the input frequency from the signal generator 32 to find the resonant frequency of the LCR circuit with the fluid 30 in the conduit 22 in the gap 20, which would also be indicative of the salinity of the fluid 30 as compared to the resonant frequency of the circuit with distilled water in the conduit 22 in the gap 20. However, the change in voltage due to loss of resonance at the set frequency f₀ when the fluid has salinity is greater or more sensitive than it is at a different resonance, because the change in output signal is greater at a just off resonance when the frequency is not changed from the set frequency f₀, as can be seen by the steep slope of the curve in FIG. 3 just off of the peak.

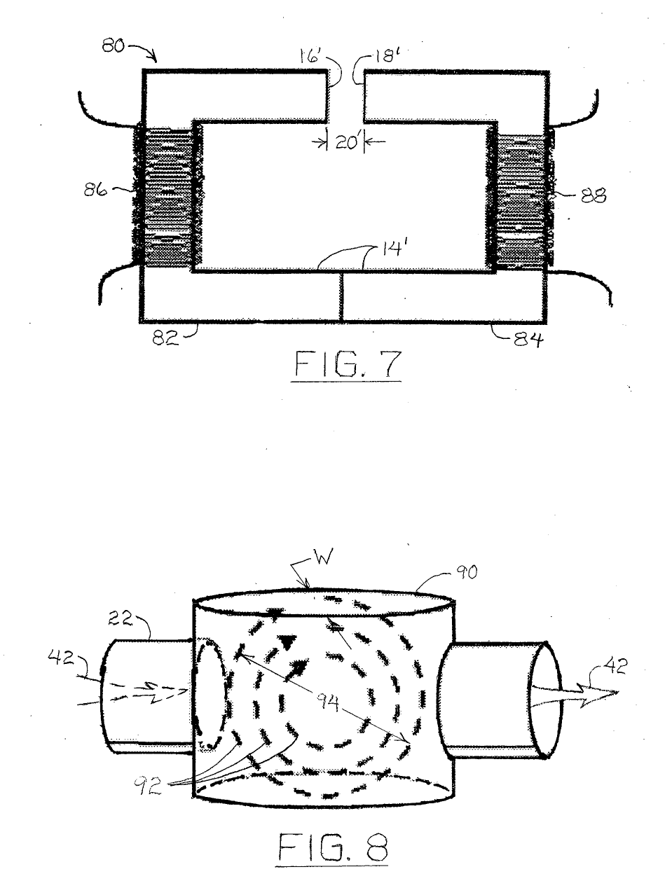

To illustrate this phenomenon, a calculated power response is shown in FIG. 3 for a non-contact, gapped core inductor salinity sensor assembled as described above using a square ferrite core, such as the core shown in FIG. 7, wired with a LCR circuit as shown in FIG. 1. To arrive at the curve in FIG. 3, a frequency response of the voltage output of the sensor was measured first with a sample of distilled water placed in the conduit 22 in the gap 20. Next, the voltage response was squared and normalized so that it could be compared to the power response curve directly. Then, equation 1 was used to calculate the power response after determining that the measured response of the circuit corresponded to an LCR circuit with values L=4.59 mH, C=105 pF, and R=200 Ohms. These values were close to the measured values of L and C for the original circuit. It was assumed that the larger R value was due to interactions with the shielding and other loss factors at frequencies greater than 100 kHz. The peak of this curve in FIG. 3 and of the output of the measured sensor occurs around 229 kHz.

Then, FIG. 4 shows the change in the voltage response curve when the distilled water sample in the conduit 22 in the gap 20 is replaced by a sample of 0.9% saline solution. The standard 0.9% saline solution is produced by mixing 900 mg of salt with 100 mL of water. The points on the chart in FIG. 4 represent data collected for the assembled sensor. The line represents the difference in the calculated voltage output for the LCR circuit described above in relation to FIG. 3 when the value of the inductance L is changed from 4.59 mH to 4.596 mH. The largest change in the measured signal occurs below the resonant frequency of approximately 229 kHz and nearer to 226 kHz. As was expected, a change in the salinity of the solution placed in the gap 20 of the magnetic core is similar to a change in the inductance of the gapped inductor. This result means that the salinity of the electrolytic solution is related to the overall output of the sensor. Also, the large change in the measured signal that occurs below the resonant frequency illustrates the observation made above that measuring the output voltage with the saline sample in the conduit 22 in the gap 20, while leaving the input voltage and frequency the same as the input voltage and resonant frequency f₀ was for the distilled water, i.e., just off resonance for the saline sample 30, places the output voltage measurements where the power response curve shows the most drastic changes in the induction L of the gapped, wound toroid and results in the most sensitivity for sensing or measurement of changes or differences in salinity of the fluid 30.

As mentioned above, the core 14 is shown in FIG. 1 in the shape of a toroid with a portion removed to create the gap 20, although it does not strictly have to be in that shape. For example, but not for limitation, other gapped core designs or shapes, such as rectangular core geometries as illustrated in FIG. 7 with square or other cross sections, would also work. The core design illustrated in FIG. 7 produces more stray fields overall than the core 14 design or configuration shown in FIG. 1, but it produces a more uniform magnetic field density in the gap 20 than the cut toroid core 14 design in FIG. 1. However, regardless of the particular core design or even of the particular coil 12 design or configuration, the purpose is to create a changing magnetic field in the fluid 30 that is strong enough to cause the charge carrying ions in the fluid to create eddy currents, as explained above. Any alternating magnetic field strong enough to serve that purpose may be satisfactory, regardless of the shape of the core 14. Also, the core 14 should, of course, be a magnetic material with high magnetic moments, such as a ferrite material, to produce a large magnetic flux density field in the core 14. The gap 20 in the core 14 causes the overall inductance value L of the circuit to drop significantly, but, as mentioned above, there is a stray magnetic field produced in the gap 20, and the material, such as the fluid 30, positioned in the gap 20 can have an effect on the overall inductance L of the circuit.

Persons having skill in the art know how to design and build electro-magnets, including toroidal coil magnets to produce alternating magnetic fields and how to design and build resonant LC and LCR circuits, and such persons can use those skills with many variations, materials, components, and embodiments to perform the functions described herein, once they understand the principles and applications of the principles described herein to sensing and/or measuring salinity as also described herein. Therefore, the example implementations described herein are just examples and not limiting or exclusive. For example, in one implementation, a partial or gapped toroidal ferrite core 14, e.g., the gapped cores shown in FIG. 1 or in FIG. 7, is wound with a number of turns of insulated magnet wire 19 based on the desired frequency of operation of the example salinity sensor apparatus 10. An example frequency of operation for that implementation was found to work well in a frequency range of about 200 to 250 kHz for several combinations of inductance and capacitance values in the LC circuit with the R of the coil winding and other inherent resistances in the circuit, but no discrete resistor. This frequency range was appropriate for the absorption spectrum of the saline solutions used for the fluid 30 being tested. The number of turns of magnet wire is related to the inductance of the wound core by L˜N² where L is the inductance and N is the number of turns. Since the resonant frequency is related to inductance L and capacitance C as described above (e.g., equation 2), the number of turns N may be selected with a consideration of an inductance value L that can be combined with a reasonable capacitance C for a final circuit. In one example implementation, a capacitance C of 10 pF was used. Also, it is helpful for the number of turns N to be high enough to provide the gapped coil 12 with a self-resonant frequency that is well above a the desirable operating frequency range to avoid self-resonance from interfering with the operation of the salinity sensor 10 functionality. The self-resonant frequency is the frequency at which the inductor will absorb some of the signal being injected into it, and the LC or LCR circuit will become very lossy near the self-resonant frequency. Therefore, changes in the signal caused by the salinity of the fluid 30 could be lost in an absorption peak of such self-resonance, so it is helpful to avoid such self-resonant frequency. Since the inductor coil 12 will behave like its own LC circuit near the self-resonant frequency due in large part to a small, but significant, inter-winding capacitance between each turn of magnet wire on the coil 12, such self-resonant frequency can be pushed to a value away from the desired operating frequency of the salinity sensor device 10 by the number of windings used. For example, if the self-resonant frequency of the coil 12 turns out to be too close to the example 200 to 250 kHz operating range mentioned above, then the self-resonant frequency can be changed, for example, to more than 300 kHz, by reducing the number windings N to avoid the self-resonant frequency from interfering with the operation of the salinity sensor 10.

The 200 to 250 kHz operating range mentioned above was found to be a good range, because the eddy current effect is stronger for higher frequencies. Therefore, while operation below that frequency range is possible with an appropriate combination of inductance and capacitance for such lower frequency operation, the resulting effect of salinity on the output signal would be weaker. Higher frequency operation may also be possible, but the signal outputs from higher frequencies tried with the particular materials, e.g., ferrite core 14 and magnet wire 19, that were used in the example salinity sensor apparatus 10 were not as good as the signal outputs obtained in the 200 to 250 kHz range. Different materials may enable better results in higher frequencies. Therefore, the signal generator 32 may be chosen for the particular operating frequency range desired. For example, for the signal generator 32 for the example salinity sensor 10 described above may be chosen for a capability to generate an AC signal of at least 250 kHz at a reasonable voltage, such as, for example, 0.250 to 0.750 V. The AC signal can be a continuous sine wave, although other waveforms can also be used. It was found that the input voltage did not have a large impact on the strength of the measured effects of salinity variations in the fluid 30, so the particular input voltage produced by the signal generator 32 is not critical. However, it may be kept in mind that common resistance losses in the circuit could cause accuracy problems if the input voltage is too low. Also, because of the resonant nature of the circuit, the voltage should not be too high, either, and it may be desirable to not exceed about 1.0 V. It may also be desirable to use shielded, co-axial cable to connect the signal generator 32 to the salinity sensor 10 and to connect the salinity sensor 10 to the AC voltage meter, as illustrated in FIG. 1, with the signals to and from the LC or LCR sensor circuit in the sensor head 50 running in the center wire of the coax cable to prevent noise in the high frequency signal or interference with external electronics.

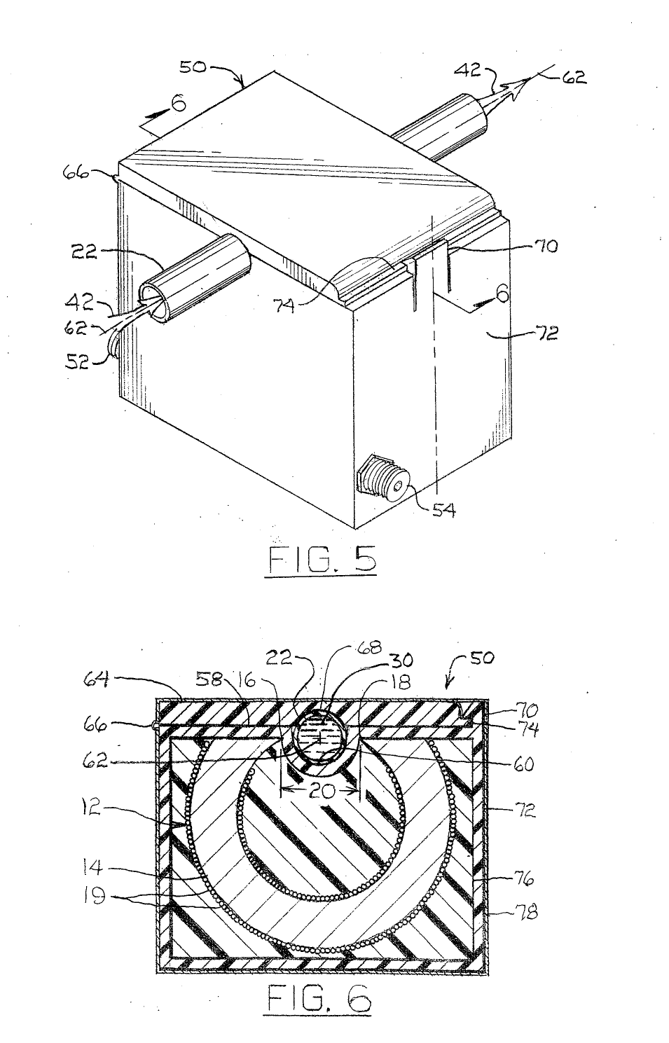

An example sensor head 50 is shown in FIGS. 5 and 6, which contains the magnetic coil 12 and internal LC or LCR circuit components to the coax connectors 52, 54 as well as a nesting and clamping structure for holding the conduit 22 in place during salinity sensing, testing, measurements, or monitoring of a fluid 30. As mentioned above, the fluid can be static in the conduit 22, or it can be flowing, as indicated by the flow arrows 42 in FIGS. 2 and 5. The conduit 22 is electrically non-conductive so that it does not interfere with the interaction of the magnetic field with the eddy currents 40 in the fluid 30. Nylon or any other non-conductive, thin walled tube can be used for the conduit 22.

The housing 56 contains the magnetic coil 12, and trough-shaped nest 60 is formed in the top wall 58 to protrude into the gap 20 between the juxtaposed ends 16, 18 of the gapped toroid core 14, as best seen in FIG. 5. The nest 60 is sized and shaped such that the conduit 22 lays snugly in trough-like shape of the nest 60 in a position where the longitudinal axis 62 is aligned with the ends 16, 18 of the magnetic core 14 so that the fluid 60 in the conduit is exposed to the strongest magnetic field in the gap 20 that is produced by the winding 19 on the core 14. A lid 64 mounted on the housing 56 by a hinge 66 also has a mating groove 68 in its bottom surface that aligns with the nest 60 in the top wall 58 and that is sized and shaped to clamp the conduit 22 snugly in the nest 60, when the lid 64 is closed and latched in place, as shown in FIG. 5. Any suitable latch or other device to hold the lid 64 in place can be used, but, in the example shown in FIG. 5, a resilient latch 70 protrudes upwardly from the sidewall 72 to engage a lip 74 that protrudes from the front edge of the lid 64.

A hardened, electrically non-conductive, epoxy shell 76 fills the remaining space in the housing 56 to secure the magnetic coil 12, and it provides some heat stability to gapped magnetic core 14 and magnetic wire winding 19. While the housing 56 is electrically non-conductive, such as plastic, to not interfere with the magnetic field created by the coil 12, an electrically conductive shield 78, for example, copper foil, is coated or plated onto the outside surfaces of the sensor head 50 to prevent stray magnetic or electric fields from interacting with other materials outside of the sensor head 50, which could alter the overall inductance L and distort the LC or LCR circuit in a manner that could alter the signal to be measured as an indication of salinity of the fluid 30. The copper shielding 78 is grounded to block fringing fields and to nullify any interaction with metal or any other conducting objects near the sensor head 50. As mentioned above, the signal generator 32 and AC voltage meter 34 (FIG. 1) are connected to the LC or LCR circuit in the sensor head 50 with coax cables so that the signal to and from the LC or LCR circuit in the sensor head 50 travels along the center conductor of the coax cable and the cable shielding is continuous across the device.

As mentioned briefly above, the salinity sensor 10 can be calibrated with distilled water. For example, distilled water can be pumped into the conduit 22 that passes through the gap 20 of the gapped core 14. This distilled water can be stationary during calibration, or it can be flowing through the conduit 22. The resonant frequency f₀ of the LC or LCR circuit with the distilled water in the conduit 22 is found by adjusting the frequency input from the signal generator 32 until the voltage output at the AC voltage meter 34 is maximized. That maximum voltage level at the resonant frequency f₀ with distilled water in the gap 20 is recorded as zero salinity. Then, the distilled water is flushed out of the conduit 22 in the gap 20 and replaced by a fluid 30 of known salinity, e.g., a solution of a known mass of NaCl dissolved in a known volume of distilled water. Again, this fluid 30 can be stationary, but it is usually kept flowing through the conduit 22, e.g., from and back into a reservoir or the like. While keeping the frequency input from the signal generator 32 at the same input voltage and frequency f₀ that was the resonant frequency with distilled water in the gap 20, the output AC voltage level is measured at the AC voltage meter 34 to correspond to the known salinity of the fluid 30 in the gap 22, which will be lower than the voltage level was at that frequency f₀ with distilled water in the gap 22, because it will no longer be resonant frequency with the saline fluid 30 in the gap 22 as it was with the distilled water in the gap 22. The output AC voltage signal versus salinity is not linear, but it is repeatable. Therefore, if there has been a curve of salinity versus voltage output constructed previously from a number of different known salinity levels, the zero salinity point and one known salinity sample point described above can be fit to such a curve for scaling, which is similar to the processing required for thermistors and is known to persons skilled in the art. If such a curve has not been constructed, then a number of additional samples of different salinity levels may have to be run to get a good curve and scale for salinity values versus AC voltage output levels.

While calibration with distilled water is convenient for a starting point, it is not necessary. The method and apparatus can also be calibrated with fluids of known salinity instead of distilled water, and the resonant frequency f₀ can ban be found for a fluid of known salinity in the gap 20 instead of for distilled water in the gap 22. Then such resonant frequency f₀ for the known salinity fluid 30 would be used along with the same input voltage from the fluid with known salinity for subsequent fluid tests or measurements of fluids with unknown salinity in much the same manner as described above. The point is that use of distilled water is a convenient, but not a necessary, benchmark for the sensor and method described herein.

After calibration as described above, a fluid 30 of unknown salinity of unknown salinity can be flowed through the conduit 22 that is in the gap 20. The output voltage measured by the AC voltage meter for the fluid 30 can then be compared to the scale created as described above to determine the salinity of the fluid 30. Such scaling and comparison can be done directly by the user or with the help of a computer or data collection device, which would be within the capabilities of persons skilled in the art, once they become familiar with the principles of this invention.

Again, as mentioned above, another method of measuring the salinity may be done by finding the resonant frequency of each different salinity fluid in the gap 20 by re-adjusting the input frequency to get the highest voltage output and noting the different resonant frequencies for the different salinities or comparing such resonant frequencies for unknown salinities to a known or calibrated curve of salinities versus resonant frequencies for the sensor. However, the method described above is more sensitive for the reasons described above. Also, is usually easier to measure a change in voltage than a change in frequency.

As mentioned briefly above, another example gapped core magnetic coil configuration 80 is shown in FIG. 7. It is more rectangular than toroidal, but it also produces a stray magnetic field in the gap 20′ between the ends 16′, 18′ of the core 14′. In this example, the core 14′ is made with two separate halves 82, 84, and two separate windings 86, 88. These windings 86, 88 can be wired in parallel or in series to fit the parameters or design needs of the LC or LCR circuit designed for the sensor. The cross section of the core 14′ can be round, square, or any other convenient shape for some or all of its length. A square cross section will produce more stray fields overall, especially with the rectangular shape instead of toroidal shape, but the field in the gap 20 will have a more uniform magnetic field density.

If a stronger output signal is needed, for example, when measuring salinity of fluids with salinity or when a better signal is needed for processing, a larger cavity for the eddy currents, as shown in FIG. 8, may be helpful. In FIG. 8, an enlarged cavity or measuring cell 90 with a width W that is still sized to fit in the gap 22 can provide more space for eddy currents 92, some with larger diameters 94 to develop, which will produce larger output signals. Also, such odd-shaped measuring cells as shown in FIG. 8 could be made even narrower in width W while still accommodating the normal flow rates though the conduit 22 with a narrower gap 22, which would increase the magnetic field strength in the fluid in the gap 22 and provide a stronger output signal.

While a number of example aspects and implementations have been discussed above, those of skill in the art will recognize certain modifications, permutations, additions, and subcombinations thereof. It is therefore intended that the following appended claims and claims thereafter introduced are interpreted to include all such modifications, permutations, additions, and subcombinations as are within their true spirit and scope.

The words “comprise,” “comprises,” “comprising,” “composed,” “composes,”, “composing,” “include,” “including,” and “includes” when used in this specification, including the claims, are intended to specify the presence of state features, integers, components, or steps, but they do not preclude the presence or addition of one or more other features, integers, components, steps, or groups thereof. Also the words “maximize” and “minimize” as used herein include increasing toward or approaching a maximum and reducing toward or approaching a minimum, respectively, even if not all the way to an absolute possible maximum or to an absolute possible minimum.

The embodiments of the invention in which an exclusive property or privilege is claimed are defined as follows:

1. A method of sensing salinity in a fluid, comprising:
placing a sample fluid having a known salinity in an alternating magnetic field created by a magnetic coil that is part of an LC or LCR circuit that is driven by a signal with an adjustable frequency;
adjusting the frequency of the LC or LCR circuit to the resonant frequency of the LC or LCR circuit with the sample fluid having the known salinity in the alternating magnetic field;
replacing the sample fluid in the alternating magnetic field with the fluid for which the salinity is to be sensed and driving the LC or LCR circuit at the same frequency as the resonant frequency of the sample fluid; and
detecting a change in a characteristic of the LC or LCR circuit that varies as a function of the salinity of a fluid in the alternating magnetic field.

2. The method of claim 1, wherein the salinity of the sample fluid is zero.

3. The method of claim 1, wherein the characteristic of the LC or LCR circuit that varies as a function of the salinity of the fluid in the alternating magnetic field is output voltage of the LC or LCR circuit.

4. The method of claim 1, wherein the characteristic of the LC or LCR circuit that varies as a function of the salinity of the fluid in the alternating magnetic field is resonant frequency of the LC or LCR circuit.

5. The method of claim 1, including creating the alternating magnetic field in a gap in a core of the magnetic coil and positioning the sample fluid in the gap while adjusting the frequency of the LC or LCR circuit to the resonant frequency of the LC or LCR circuit; and then replacing the sample fluid in the gap with the fluid for which salinity is to be sensed.

6. The method of claim 5, including flowing the sample fluid through a conduit positioned in the gap while the frequency of the LC or LCR circuit is adjusted to the resonant frequency, and then flowing the fluid for which salinity is to be sensed through the conduit that is positioned in the gap while maintaining the frequency of the LC or LCR circuit at the same frequency as the resonant frequency of the LC or LCR circuit when the sample fluid was flowing through the conduit in the gap.

7. The method of claim 6, including detecting the change in the characteristic of the LC or LCR circuit when the fluid for which the salinity is to be sensed has replaced the sample fluid in the conduit in the gap.

8. The method of claim 1, including adjusting the frequency of the LC or LCR circuit to a frequency in a range of 200 to 250 kHz.

9. The method of claim 1, including:
detecting the characteristic of the LC or LCR circuit that varies as a function of salinity of the fluid in the alternating magnetic field when the sample fluid is in the alternating magnetic field;
replacing the sample fluid in the alternating magnetic field with a second sample fluid for which the salinity is known before placing the sample fluid for which salinity is to be detected in the alternating magnetic field;
driving the LC or LCR circuit with the second sample in the alternating magnetic field at the same frequency as the resonant frequency of the sample fluid that was replaced;
detecting the characteristic of the LC or LCR circuit that varies as a function of salinity of the fluid in the alternating magnetic field when the second sample fluid is in the alternating magnetic field; and
creating a scale of salinity in relation to the characteristic of the LC or LCR circuit that varies as a function of salinity of the fluid in the alternating magnetic field with the values of the characteristic detected for both the sample fluid and the second sample fluid.

10. The method of claim 9, including:
placing the value of the characteristic of the LC or LCR circuit that varies as a function of salinity of the fluid in the alternating magnetic field that is detected for the fluid for which the salinity is to be determined in the scale; and
determining the salinity of the fluid from the scale.

11. Apparatus for sensing salinity of a fluid, comprising:
a magnetic coil that is part of a LC or LCR circuit;
a signal generator with an adjustable frequency connected to the LC or LCR circuit for driving the magnetic coil to create an alternating magnetic field;
a AC voltage meter connected to the LC or LCR circuit for measuring output voltage of the LC or LCR circuit; and
a container capable of containing the fluid positioned adjacent the magnetic coil where the fluid in the container is exposed to the alternating magnetic field created by the magnetic coil.

12. The apparatus of claim 11, wherein the container is a conduit that is capable of conducting the fluid flowing through the alternating magnetic field.

13. The apparatus of claim 12, wherein the magnetic coil includes a gapped core and the conduit is positioned in the gap so that the fluid can flow though the conduit in the gap.

14. Apparatus for sensing salinity in a fluid, comprising:
means for placing a sample fluid having a known salinity in an alternating magnetic field created by a magnetic coil that is part of an LC or LCR;
means for driving the LC or LCR circuit with an adjustable frequency;
means for adjusting the frequency of the LC or LCR circuit to the resonant frequency of the LC or LCR circuit with the sample fluid having the known salinity in the alternating magnetic field;
means for replacing the sample fluid in the alternating magnetic field with the fluid for which the salinity is to be sensed while driving the LC or LCR circuit at the same frequency as the resonant frequency of the sample fluid; and
means for detecting a change in a characteristic of the LC or LCR circuit that varies as a function of the salinity of a fluid in the alternating magnetic field.
